(19) United States
(12) Patent Application Publication
(10) Pub. No.: US 2026/0262317 A1
(43) Pub. Date: Sep. 3, 2026

(54) SEMICONDUCTOR DEVICE

(71) Applicant: SONY SEMICONDUCTOR SOLUTIONS CORPORATION, KANAGAWA (JP)

(72) Inventor: AKIHISA SAKAMOTO, KANAGAWA (JP)

(21) Appl. No.: 19/162,162

(22) PCT Filed: Mar. 19, 2024
(86) PCT No.: PCT/JP2024/010670

§ 371 Date: Sep. 4, 2025

(30) Foreign Application Priority Data
Mar. 20, 2023 (JP) 2023-043739

(51) Int. Cl. H10F 39/00

(52) U.S. Cl. CPC H10F 39/809; H10F 39/018

(57) ABSTRACT

To easily perform planarization of an insulating film covering a semiconductor chip bonded to a back surface side of an imaging element. A semiconductor device of the present disclosure includes a first semiconductor substrate, a second semiconductor substrate, and a covering member. The second semiconductor substrate included in the semiconductor device of the present disclosure is bonded to the first semiconductor substrate included in the semiconductor device of the present disclosure, and includes a protrusion on a surface different from a surface to be bonded. The covering member included in the semiconductor device of the present disclosure covers the second semiconductor substrate bonded to the first semiconductor substrate.

### FIELD

The present disclosure relates to a semiconductor device.

### BACKGROUND

A semiconductor device is used in which a semiconductor chip including a logic circuit that processes an image signal is stacked on an imaging element in which pixels that generates the image signal according to incident light are arranged in a two-dimensional matrix. As an imaging element used in such a semiconductor device, a backside irradiation type imaging element is applied in which a back surface side of a semiconductor substrate is irradiated with incident light. A front surface side of the semiconductor chip is bonded to and stacked on a front surface side of the imaging element. In a method of connecting the imaging element and the semiconductor chip, Cu—Cu connection is used in which copper (Cu) pads arranged in the respective wiring regions are bonded to each other to obtain electrical connection.

Meanwhile, a process of, for example, arranging a color filter or an on-chip lens that condenses incident light is required on the back surface side of the imaging element.

Therefore, there has been proposed a semiconductor device (solid-state imaging device) generated by adhering a support substrate such as a silicon wafer to a back surface side of a semiconductor chip bonded to a front surface side of an imaging element and turning the support substrate upside down, and executing a process on the back surface side of the imaging element (see, for example, Patent Literature 1).

### CITATION LIST

### Patent Literature

Patent Literature 1: WO 2019/087764 A

### SUMMARY

### Technical Problem

In the conventional technique described above, an oxide film for adhering a support substrate is formed on a back surface side of a semiconductor chip. By planarizing the oxide film and thermocompression-bonding the support substrate, the semiconductor chip and the support substrate are bonded via the oxide film. However, since the area of the semiconductor chip is smaller than that of an imaging element, there is a region on the back surface side of the imaging element where the semiconductor chip is not arranged. For this reason, there is a problem that a relatively large step is formed in the oxide film covering the semiconductor chip making it difficult to planarize the oxide film.

Therefore, the present disclosure proposes a semiconductor device that easily performs planarization of an insulating film covering a semiconductor chip bonded to a back surface side of an imaging element.

### Solution to Problem

A semiconductor device according to the present disclosure includes: a first semiconductor substrate; a second semiconductor substrate that is bonded to the first semiconductor substrate and includes a protrusion on a surface different from a surface to be bonded; and a covering member that covers the second semiconductor substrate bonded to the first semiconductor substrate.

### BRIEF DESCRIPTION OF DRAWINGS

FIG. 1 is a view illustrating a configuration example of a semiconductor device according to a first embodiment of the present disclosure.

FIG. 2 is a cross-sectional view illustrating the configuration example of the semiconductor device according to the first embodiment of the present disclosure.

FIG. 3A is a view illustrating an example of a configuration of a covering member in a conventional technique.

FIG. 3B is a view illustrating an example of the configuration of the covering member in the conventional technique.

FIG. 4 is a view illustrating a configuration example of a protrusion according to the first embodiment of the present disclosure.

FIG. 5 is a view illustrating an example of a shape of a protrusion according to the first embodiment of the present disclosure.

FIG. 6A is a graph indicating a relationship between a step of a material film and a shape of the protrusion according to the first embodiment of the present disclosure.

FIG. 6B is a graph indicating a relationship between a polishing rate of the material film and the shape of the protrusion according to the first embodiment of the present disclosure.

FIG. 7A is a view illustrating an example of a method of manufacturing a semiconductor chip according to the first embodiment of the present disclosure.

FIG. 7B is a view illustrating an example of the method of manufacturing the semiconductor chip according to the first embodiment of the present disclosure.

FIG. 7C is a view illustrating an example of the method of manufacturing the semiconductor chip according to the first embodiment of the present disclosure.

FIG. 7D is a view illustrating an example of the method of manufacturing the semiconductor chip according to the first embodiment of the present disclosure.

FIG. 7E is a view illustrating an example of the method of manufacturing the semiconductor chip according to the first embodiment of the present disclosure.

FIG. 8A is a view illustrating an example of a method of manufacturing the semiconductor device according to the first embodiment of the present disclosure.

FIG. 8B is a view illustrating an example of the method of manufacturing the semiconductor device according to the first embodiment of the present disclosure.

FIG. 8C is a view illustrating an example of the method of manufacturing the semiconductor device according to the first embodiment of the present disclosure.

FIG. 8D is a view illustrating an example of the method of manufacturing the semiconductor device according to the first embodiment of the present disclosure.

FIG. 8E is a view illustrating an example of the method of manufacturing the semiconductor device according to the first embodiment of the present disclosure.

FIG. 8F is a view illustrating an example of the method of manufacturing the semiconductor device according to the first embodiment of the present disclosure.

FIG. 8G is a view illustrating an example of the method of manufacturing the semiconductor device according to the first embodiment of the present disclosure.

FIG. 8H is a view illustrating an example of the method of manufacturing the semiconductor device according to the first embodiment of the present disclosure.

FIG. 9A is a view illustrating another configuration example of the protrusion according to the first embodiment of the present disclosure.

FIG. 9B is a view illustrating the other configuration example of the protrusion according to the first embodiment of the present disclosure.

FIG. 10A is a view illustrating a configuration example of a protrusion according to a second embodiment of the present disclosure.

FIG. 10B is a view illustrating a configuration example of the protrusion according to the second embodiment of the present disclosure.

FIG. 11A is a view illustrating an example of a method of manufacturing a semiconductor chip according to the second embodiment of the present disclosure.

FIG. 11B is a view illustrating an example of the method of manufacturing the semiconductor chip according to the second embodiment of the present disclosure.

FIG. 11C is a view illustrating an example of the method of manufacturing the semiconductor chip according to the second embodiment of the present disclosure.

FIG. 12A is a view illustrating another configuration example of the protrusion according to the second embodiment of the present disclosure.

FIG. 12B is a view illustrating another configuration example of the protrusion according to the second embodiment of the present disclosure.

FIG. 13 is a view illustrating a configuration example of a protrusion according to a third embodiment of the present disclosure.

FIG. 14A is a view illustrating an example of a method of manufacturing a semiconductor chip according to the third embodiment of the present disclosure.

FIG. 14B is a view illustrating an example of the method of manufacturing the semiconductor chip according to the third embodiment of the present disclosure.

FIG. 15 is a view illustrating a configuration example of a semiconductor device according to a fourth embodiment of the present disclosure.

FIG. 16 is a view illustrating another configuration example of the semiconductor device according to the fourth embodiment of the present disclosure.

FIG. 17 is a view illustrating another configuration example of the semiconductor device according to the fourth embodiment of the present disclosure.

FIG. 18 is a view illustrating another configuration example of the semiconductor device according to the fourth embodiment of the present disclosure.

### DESCRIPTION OF EMBODIMENTS

Hereinafter, embodiments of the present disclosure will be described in detail with reference to the drawings. The description will be given in the following order. In each of the following embodiments, the same parts are denoted by the same reference numerals, and redundant description will be omitted.
1. First Embodiment

1 2. Second Embodiment
3. Third Embodiment
4. Fourth Embodiment

### 1. First Embodiment

### [Configuration of Semiconductor Device]

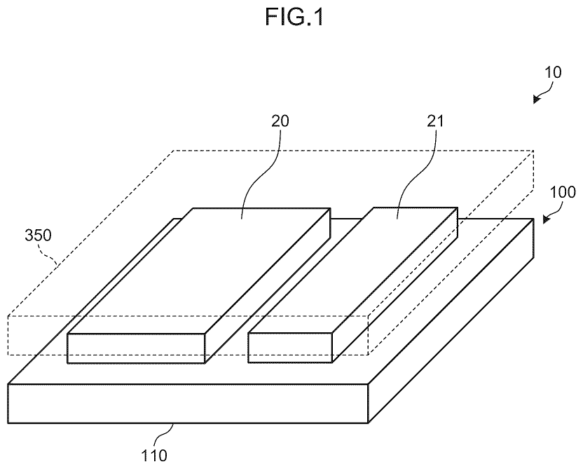

FIG. 1 is a view illustrating a configuration example of a semiconductor device according to a first embodiment of the present disclosure. FIG. 1 is a view illustrating a configuration example of a semiconductor device 10. The semiconductor device 10 in FIG. 1 illustrates an example in which semiconductor chips 20 and 21 are stacked on a front surface side of an imaging element 100 that images a subject and generates an image signal, and a third semiconductor substrate 350 is further stacked. The third semiconductor substrate 350 corresponds to the support substrate described above. A dotted line in FIG. 1 indicates the shape of the third semiconductor substrate 350. The semiconductor chip 20 corresponds to, for example, a semiconductor chip including a circuit that processes the image signal generated by the imaging element 100. In addition, the semiconductor chip 21 corresponds to, for example, a semiconductor chip including a circuit that performs artificial intelligence (AI) processing. By stacking the semiconductor chip 20 and the like on the imaging element 100, the semiconductor device 10 can be downsized. Note that the imaging element 100 in FIG. 1 includes a first semiconductor substrate 110.

### [Configuration of Cross-Section of Semiconductor Device]

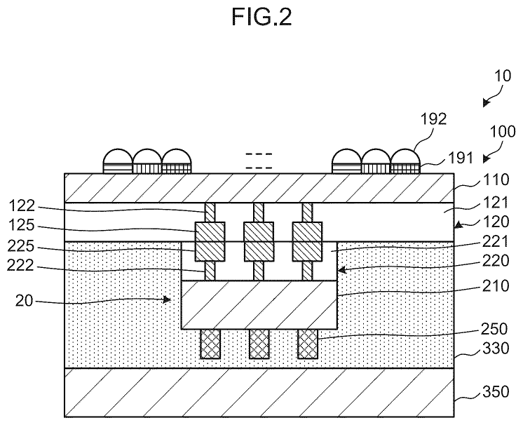

FIG. 2 is a cross-sectional view illustrating the configuration example of the semiconductor device according to the first embodiment of the present disclosure. FIG. 2 is a schematic cross-sectional view illustrating the configuration example of the semiconductor device 10. The semiconductor device 10 in FIG. 2 includes the imaging element 100, the semiconductor chip 20, a covering member 330, and the third semiconductor substrate 350.

The imaging element 100 includes the first semiconductor substrate 110, a wiring region 120, a color filter 191, and an on-chip lens 192.

The first semiconductor substrate 110 is a semiconductor substrate in which a plurality of pixels including a photoelectric conversion unit that performs photoelectric conversion of incident light is arranged. The first semiconductor substrate can be made of, for example, silicon (Si).

The wiring region 120 is a region formed on the front surface side of the first semiconductor substrate 110 and in which wiring is arranged. The wiring region 120 includes an insulating layer 121 and wirings 122. The wiring 122 is a conductor that transmits an electric signal. The wiring 122 can be made of copper (Cu) or tungsten (W). The insulating layer 121 insulates the wiring 122 and the like. The insulating layer 121 can be made of, for example, SiO₂. In addition, the insulating layer 121 constitutes an oxide film bonding layer for bonding to an insulating layer 221 of a wiring region 220 of a second semiconductor substrate 210 described later. Pads 125 are arranged on a front surface of the insulating layer 121. The pad 125 is an electrode having a shape embedded in the insulating layer 121. The pad 125 can be made of Cu. The pad 125 is a pad bonded to a pad 225 in the wiring region 220 of the second semiconductor substrate 210.

The color filter 191 is an optical filter that transmits light of a predetermined wavelength among incident light. In addition, the on-chip lens 192 is a lens that condenses incident light.

The semiconductor chip 20 includes the second semiconductor substrate 210, the wiring region 220, and protrusions 250.

The second semiconductor substrate 210 is a semiconductor substrate on which a circuit that processes the image signal generated by the imaging element 100 is arranged.

The second semiconductor substrate 210 can be made of, for example, Si.

The wiring region 220 is formed on a front surface side of the second semiconductor substrate 210 and includes wirings 222 and the insulating layer 221. Similarly to the insulating layer 121, the insulating layer 221 can be made of SiO₂. In addition, pads 225 having a shape embedded in a front surface of the insulating layer 221 is arranged in the wiring region 220. When the semiconductor chip 20 is bonded to the imaging element 100, the insulating layers 121 and 221 are adhered and bonded. At this time, the pads 125 and 225 are bonded and used for signal transmission between the imaging element 100 and the semiconductor chip 20. Such a connection method is referred to as Cu—Cu connection.

The protrusion 250 is a protruding region arranged on a back surface side of the second semiconductor substrate 210.

The protrusion 250 alleviates a step formed when the covering member 330 described later is arranged on a back surface side of the semiconductor chip 20. FIG. 2 illustrates an example in which a plurality of the protrusions 250 is arranged.

The protrusion 250 in FIG. 2 can include a member having thermal conductivity higher than that of the second semiconductor substrate 210. Specifically, the protrusion 250 can be made of silicon carbide (SiC), aluminum nitride (AlN), and silicon nitride (SiN).

In addition, the protrusion 250 in FIG. 2 can also include a member that suppresses etching of the second semiconductor substrate 210 when the covering member 330 is dry-etched. The member that suppresses etching of the second semiconductor substrate 210 is also referred to as an etching stopper. Specifically, the protrusion 250 can be made of aluminum oxide (Al₂O₃), SiC, AlN, and SiN.

The covering member 330 covers the back surface side of the semiconductor chip 20. The covering member 330 in FIG. 2 further covers the back surface and side surface of the second semiconductor substrate 210 and the wiring region 120 on the front surface side of the first semiconductor substrate 110. The covering member 330 can be made of, for example, an inorganic material such as SiO₂, SiON, SiCHO, SiN, and spin on glass (SOG), or an organic material such as a silicon resin, a siloxane resin, and a polyimide resin.

The third semiconductor substrate 350 is a substrate that is stacked on the back surface side of the semiconductor chip 20 and supports the imaging element 100 and the semiconductor chip 20. A silicon wafer or the like can be applied to the third semiconductor substrate 350. The third semiconductor substrate 350 in FIG. 2 is bonded to the back surface side of the semiconductor chip 20 via the covering member 330.

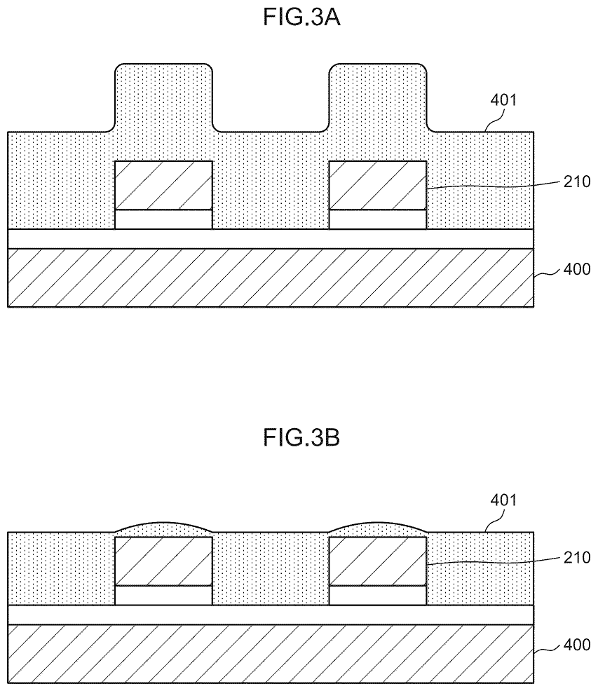

FIGS. 3A and 3B are views illustrating examples of a configuration of a covering member in a conventional technique.

FIG. 3A illustrates a state in which a material film 401 of the covering member 330 is formed by chemical vapor deposition (CVD) or the like in a state in which a plurality of second semiconductor substrates 210 is bonded to a semiconductor substrate 400. As illustrated in FIG. 3A, a large step is formed on a surface of the material film 401. Next, the surface of the material film 401 is ground by chemical mechanical polishing (CMP) or the like, and the surface of the material film 401 is planarized to bond the third semiconductor substrate 350.

FIG. 3B illustrates the covering member 330 after the planarization. FIG. 3B illustrates an example in which planarization cannot be performed because of the step portion and a bulge occurs in the vicinity of the second semiconductor substrate 210. In the case where the planarization of the covering member 330 is not sufficient, the bonding strength of the third semiconductor substrate 350 decreases. As described above, it is difficult to planarize the covering member 330 because of the step formed by the second semiconductor substrate 210.

### [Configuration of Protrusion]

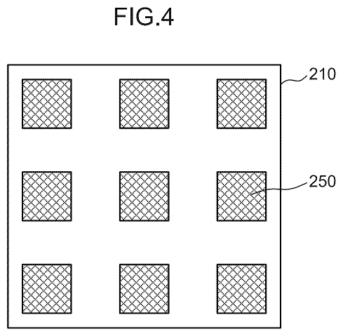

FIG. 4 is a view illustrating a configuration example of the protrusion according to the first embodiment of the present disclosure. FIG. 4 is a plan view illustrating a configuration example of the protrusion 250. FIG. 4 illustrates the configuration example of the protrusions 250 arranged on the back surface of the second semiconductor substrate 210 of the semiconductor chip 20. FIG. 4 illustrates an example in which the protrusions 250 each has a rectangular shape in plan view. In addition, FIG. 4 illustrates an example in which the protrusions 250 are arranged in 3 rows and 3 columns.

### [Shape of Protrusion]

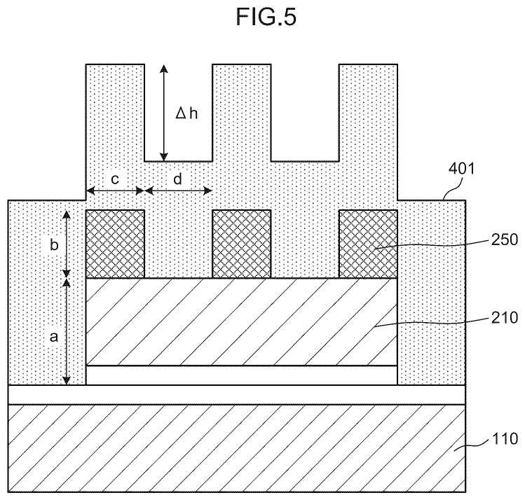

FIG. 5 is a view illustrating an example of a shape of the protrusion according to the first embodiment of the present disclosure. FIG. 5 illustrates a state in which the material film 401 of the covering member 330 is arranged on the second semiconductor substrate 210 bonded to the first semiconductor substrate 110. In FIG. 5, “a” represents the height from a bonding surface of the second semiconductor substrate 210, that is, the thickness of the second semiconductor substrate 210 including the wiring region 120. In addition, “b” represents the height of the protrusion 250. In addition, “c” represents the width of the protrusion 250. In addition, “d” represents the distance to the adjacent protrusion 250. In addition, “Δh” represents the step of the material film 401 in the vicinity of the protrusion 250.

As illustrated in FIG. 5, by arranging the plurality of protrusions 250 on the front surface side of the second semiconductor substrate 210, the material film 401 between the protrusions 250 can be thinned. This is because step coverage of the material film 401 formed by CVD or the like is deteriorated. Note that the protrusion 250 can have a shape in which the height (b) is smaller than the height (a) from the bonding surface of the second semiconductor substrate 210.

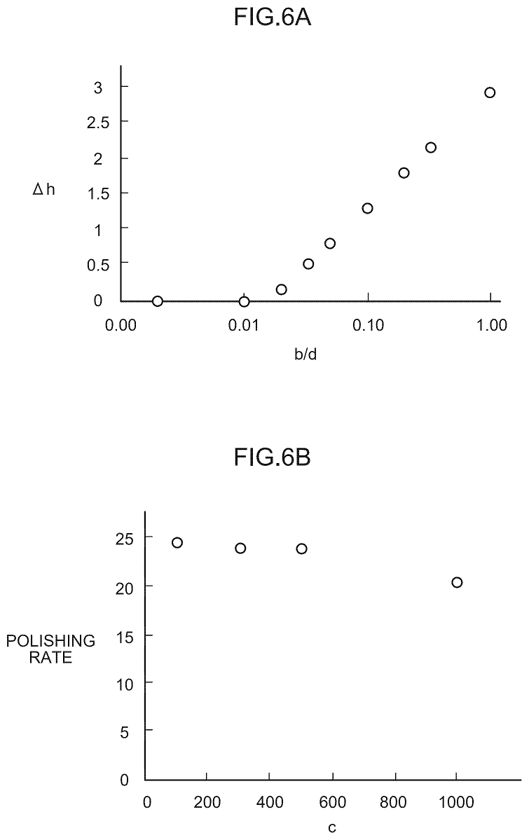

FIG. 6A is a graph indicating a relationship between the step of the material film and the shape of the protrusion according to the first embodiment of the present disclosure.

FIG. 6A is a graph indicating the relationship between (4h) in FIG. 5 and the ratio (b/d) of the height of the protrusion 250 to the distance to the adjacent protrusion 250. The horizontal axis in FIG. 6A represents the ratio (b/d). In addition, the vertical axis in FIG. 6A represents the step (Δh) in FIG. 5. The unit is [μm]. As illustrated in FIG. 6A, the step (Δh) can be reduced in a region where the ratio (b/d) is smaller than 0.01.

FIG. 6B is a graph indicating a relationship between a polishing rate of the material film and the shape of the protrusion according to the first embodiment of the present disclosure. FIG. 6B is a graph indicating the relationship between the polishing rate of the material film 401 in CMP and the width (c) of the protrusion 250 in FIG. 5. The horizontal axis in FIG. 6B represents the width (c). The unit is [μm]. The vertical axis in FIG. 6B represents the polishing rate. The unit is [nm/s]. As illustrated in FIG. 6B, in a case where the width (c) of the protrusion 250 exceeds 500 μm, the polishing rate decreases. Therefore, the width (c) of the protrusion 250 is preferably 500 μm or less.

### [Method of Manufacturing Semiconductor Chip]

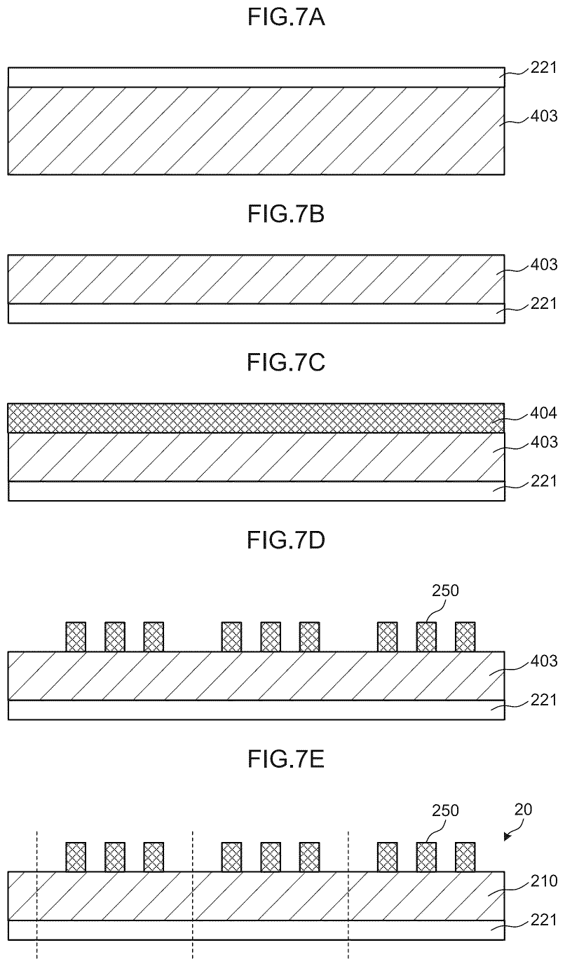

FIGS. 7A to 7E are views illustrating an example of a method of manufacturing the semiconductor chip according to the first embodiment of the present disclosure. FIGS. 7A to 7E are views illustrating examples of processes of manufacturing the semiconductor chip 20. First, the insulating layer 221 is arranged on a semiconductor substrate 403 which is an original substrate of the second semiconductor substrate 210 (FIG. 7A).

Next, the back surface side of the semiconductor substrate 403 is ground to be thinned (FIG. 7B). Next, the material film 404 of the protrusion 250 is arranged on the back surface side of the semiconductor substrate 403 (FIG. 7C). Next, the material film 404 is etched to form the protrusion 250 (FIG. 7D). Next, the semiconductor substrate 403 is diced into individual pieces (FIG. 7E). As a result, the semiconductor chip 20 can be formed.

### [Method of Manufacturing Semiconductor Device]

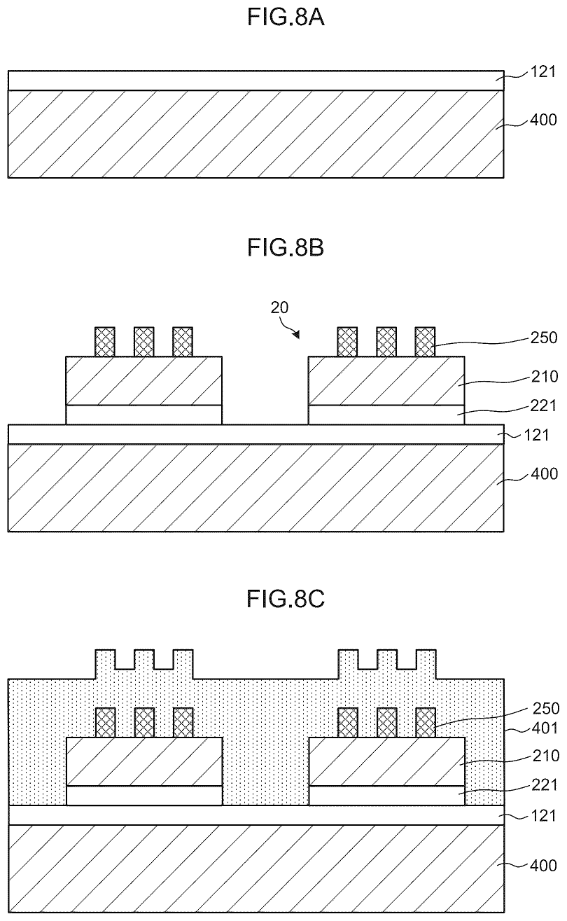

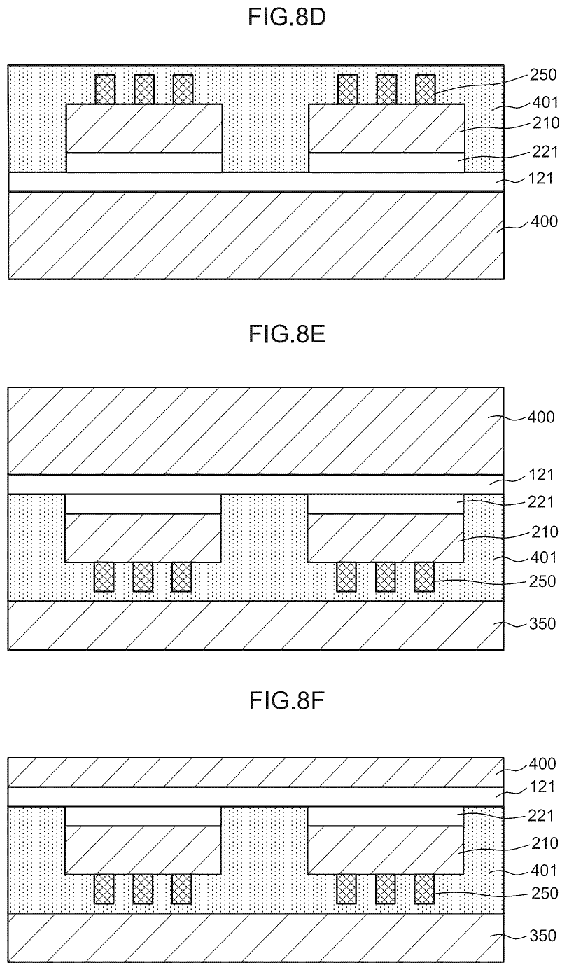

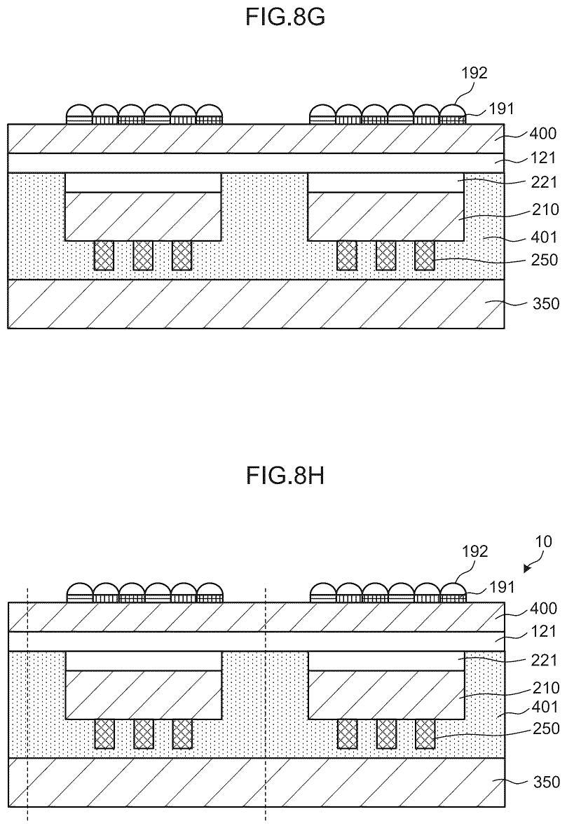

FIGS. 8A to 8H are views illustrating an example of a method of manufacturing the semiconductor device according to the first embodiment of the present disclosure. FIGS. 8A to 8H are views illustrating examples of processes of manufacturing the semiconductor device 10. First, the insulating layer 121 is formed on the semiconductor substrate 400 which is an original substrate of the first semiconductor substrate 110 (FIG. 8A).

Next, the semiconductor chip 20 is arranged (FIG. 8B). Next, the material film 401 of the covering member 330 is arranged (FIG. 8C). Next, the material film 401 is ground and planarized (FIG. 8D). Next, the semiconductor substrate 400 is turned upside down and bonded to the third semiconductor substrate 350 (FIG. 8E).

Next, the semiconductor substrate 400 is ground to be thinned (FIG. 8F). Next, the color filter 191 and the on-chip lens 192 are arranged on the back surface side of the semiconductor substrate 400 (FIG. 8G). Next, the semiconductor substrate 400 and the third semiconductor substrate 350 are diced into individual pieces (FIG. 8H). As a result, the semiconductor device 10 can be manufactured.

### [Another Configuration of Protrusion]

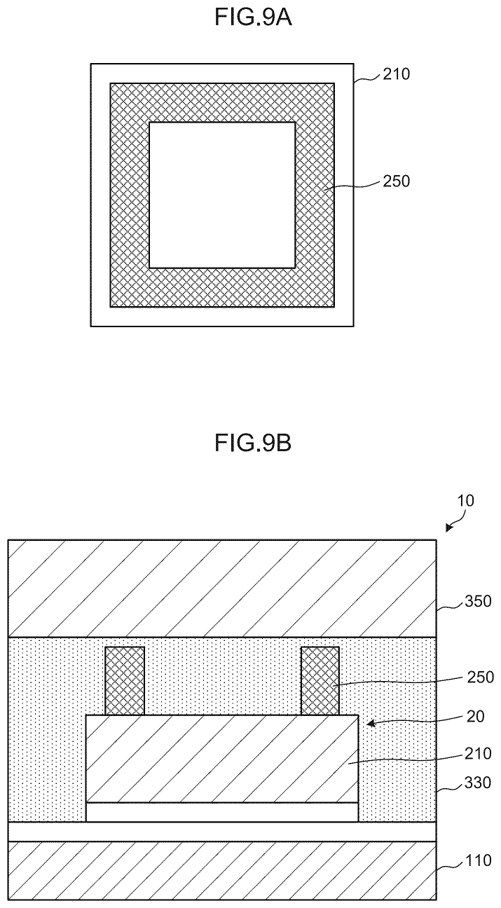

FIGS. 9A and 9B are views illustrating another configuration example of the protrusion according to the first embodiment of the present disclosure. FIG. 9A is a plan view illustrating a configuration example of the protrusion 250 similarly to FIG. 4. The protrusion 250 in FIG. 9A is different from the protrusion 250 in FIG. 4 in being formed in a wall shape along an end portion of the second semiconductor substrate 210.

FIG. 9B is a schematic cross-sectional view illustrating the configuration example of the protrusion 250. In FIG. 9B, the first semiconductor substrate 110, the covering member 330, and the third semiconductor substrate 350 are further illustrated.

As described above, in the semiconductor device 10 according to the first embodiment of the present disclosure, the protrusion is formed on the back surface side of the second semiconductor substrate 210 in which its front surface side is bonded to and stacked on the front surface side of the first semiconductor substrate 110. As a result, the step of the covering member 330 arranged in a shape covering the back surface of the second semiconductor substrate 210 can be alleviated. Therefore, grinding for planarizing the covering member 330 can be easily performed.

### 2. Second Embodiment

The semiconductor device 10 according to the first embodiment described above includes the protrusion 250 including a member having a thermal conductivity higher than that of the second semiconductor substrate 210 and a member that suppresses etching of the second semiconductor substrate 210 when the covering member 330 is dry-etched. On the other hand, a semiconductor device 10 according to a second embodiment of the present disclosure is different from that of the first embodiment described above in including a protrusion 250 including the same member as that of a second semiconductor substrate 210.

### [Configuration of Protrusion]

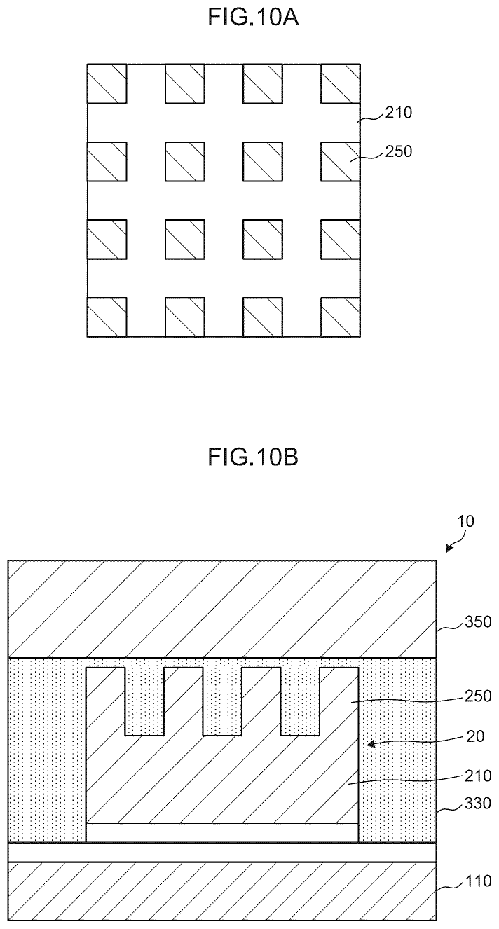

FIGS. 10A and 10B are views illustrating a configuration example of the protrusion according to the second embodiment of the present disclosure. FIG. 10A is a plan view illustrating a configuration example of the protrusion 250 similarly to FIG. 4. The protrusion 250 in FIG. 10A is different from the protrusion 250 in FIG. 4 in that the protrusion 250 includes the same member as the second semiconductor substrate 210 of a semiconductor chip 20.

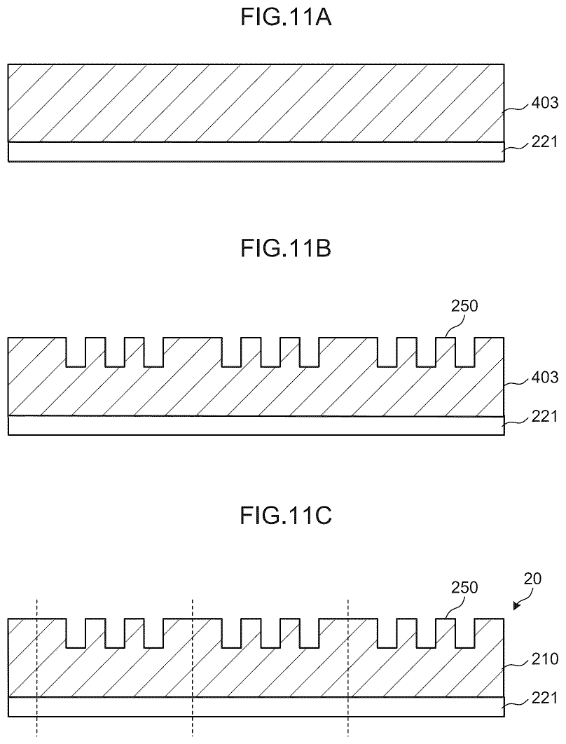

FIG. 10B is a schematic cross-sectional view illustrating the configuration example of the protrusion 250 similarly to FIG. 9B. In FIG. 10B, a first semiconductor substrate 110, a covering member 330, and a third semiconductor substrate 350 are further illustrated. The protrusion 250 in FIG. 10B is an example including a part of the second semiconductor substrate 210.

[Method of Manufacturing Semiconductor Chip] FIGS. 11A to 11C are views illustrating an example of a method of manufacturing the semiconductor chip according to the second embodiment of the present disclosure. FIGS. 11A to 11C are views illustrating examples of processes of manufacturing the semiconductor chip 20 similarly to FIGS. 7A to 7E. Similarly to FIG. 7A, first, an insulating layer 221 is arranged on a semiconductor substrate 403 which is an original substrate of the second semiconductor substrate 210 (FIG. 11A). Next, a part of a back surface side of the semiconductor substrate 403 is ground to form the protrusion 250 (FIG. 11B). This can be performed, for example, by forming a dicing slit on the back surface side of the semiconductor substrate 403. Next, the semiconductor substrate 403 is diced into individual pieces (FIG. 11C). As a result, the semiconductor chip 20 can be formed.

### [Another Configuration of Protrusion]

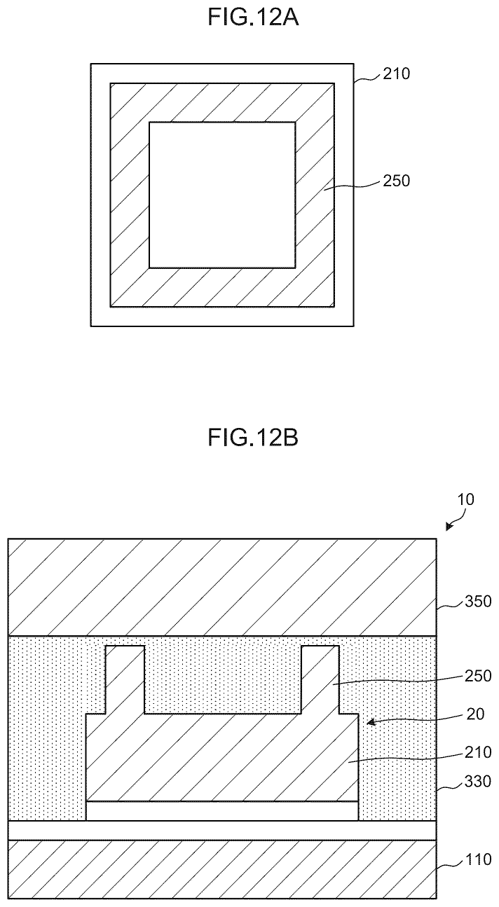

FIGS. 12A and 12B are views illustrating another configuration example of the protrusion according to the second embodiment of the present disclosure. FIG. 12A is a plan view illustrating a configuration example of the protrusion 250 similarly to FIG. 9A. In addition, FIG. 12B is a schematic cross-sectional view illustrating the configuration example of the protrusion 250 similarly to FIG. 9B. The protrusion 250 in FIGS. 12A and 12B is different from the protrusion 250 in FIGS. 9A and 9B in that the protrusion includes a part of the second semiconductor substrate 210.

Since the configuration of the semiconductor device 10 other than the above is similar to the configuration of the semiconductor device 10 in the first embodiment of the present disclosure, the description thereof will be omitted.

As described above, the semiconductor device 10 according to the second embodiment of the present disclosure includes the protrusion 250 including the same member as the second semiconductor substrate 210. Thus, the processes of manufacturing the protrusion 250 can be simplified.

### 3. Third Embodiment

The semiconductor device 10 according to the second embodiment described above includes the protrusion 250 including the same member as the second semiconductor substrate 210. On the other hand, a semiconductor device 10 according to a third embodiment of the present disclosure is different from that of the second embodiment described above in including a protrusion 250 including a member having a thermal conductivity higher than that of a second semiconductor substrate 210 and a member that suppresses etching of the second semiconductor substrate 210 during dry etching.

### [Configuration of Protrusion]

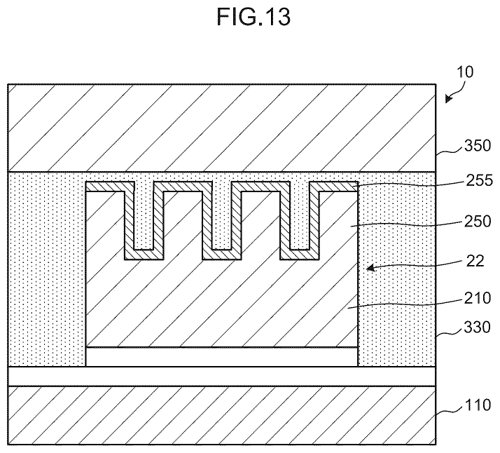

FIG. 13 is a view illustrating a configuration example of the protrusion according to the third embodiment of the present disclosure. FIG. 13 is a schematic cross-sectional view illustrating a configuration example of a semiconductor chip 22. The semiconductor chip 22 in FIG. 13 illustrates an example in which a protrusion 250 including a plurality of members is provided. The protrusion 250 in FIG. 13 is formed by arranging a coating film 255 on a surface of the protrusion including a part of the second semiconductor substrate 210. The coating film 255 can include, for example, a member having a thermal conductivity higher than that of the second semiconductor substrate 210. In addition, the coating film 255 can also include, for example, a member that suppresses etching of the second semiconductor substrate 210. Furthermore, the coating film 255 formed by stacking these members can also be used. In this case, the member that suppresses etching is preferably arranged on a front surface side.

### [Method of Manufacturing Semiconductor Chip]

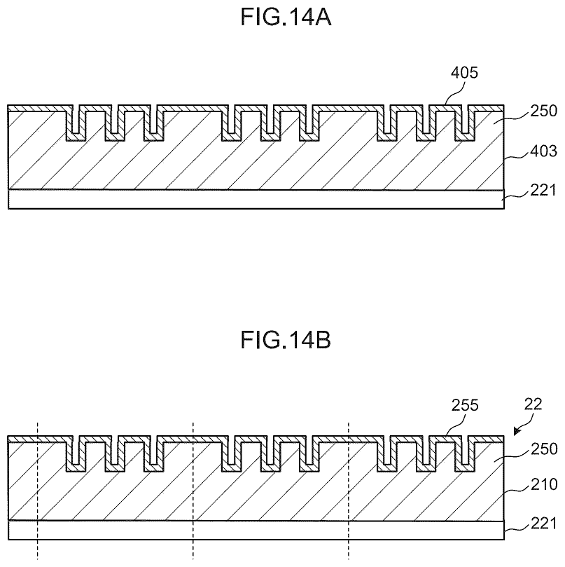

FIGS. 14A and 14B are views illustrating an example of a method of manufacturing the semiconductor chip according to the third embodiment of the present disclosure. FIGS. 14A and 14B are views illustrating examples of processes of manufacturing the semiconductor chip 22 similarly to FIGS. 11A to 11C. First, the processes in FIGS. 11A and 11B are executed. Next, a material film 405 of the coating film 255 is arranged on a back surface side of the semiconductor substrate 403 (FIG. 14A).

Next, the semiconductor substrate 403 is diced into individual pieces (FIG. 14B). As a result, the semiconductor chip 22 can be formed.

Since the configuration of the semiconductor device 10 other than the above is similar to the configuration of the semiconductor device 10 in the second embodiment of the present disclosure, the description thereof will be omitted.

As described above, the semiconductor device 10 according to the third embodiment of the present disclosure includes the protrusion 250 including the coating film 255 which includes the same member as the second semiconductor substrate 210 and the high thermal conductivity member.

### 4. Fourth Embodiment

Variations of a semiconductor device 10 will be described.

### [Configuration of Semiconductor Device]

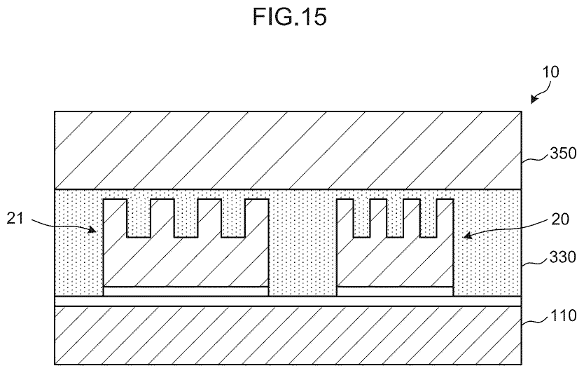

FIG. 15 is a view illustrating a configuration example of a semiconductor device according to a fourth embodiment of the present disclosure. FIG. 15 is a schematic cross-sectional view illustrating a configuration example of a semiconductor device 10 similarly to FIG. 10B. The semiconductor device 10 in FIG. 15 illustrates an example in which a plurality of semiconductor chips (semiconductor chips 20 and 21) is provided.

### [Another Configuration of Semiconductor Device]

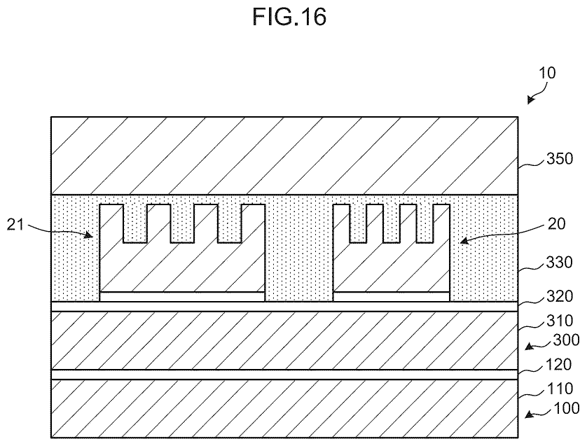

FIG. 16 is a view illustrating another configuration example of the semiconductor device according to the fourth embodiment of the present disclosure. FIG. 16 is a schematic cross-sectional view illustrating a configuration example of the semiconductor device 10 similarly to FIG. 15. The semiconductor device 10 in FIG. 16 illustrates an example in which a memory chip 300 is further provided.

The memory chip 300 is a semiconductor chip on which a semiconductor memory element is arranged. The memory chip 300 in FIG. 16 is an example configured to have the same size as an imaging element 100. The memory chip 300 includes a fourth semiconductor substrate 310 and a wiring region 320. In addition, the memory chip 300 is bonded to a front surface side of the imaging element 100. The semiconductor chips 20 and 21 are bonded to the wiring region 320 on the front surface side of the memory chip 300.

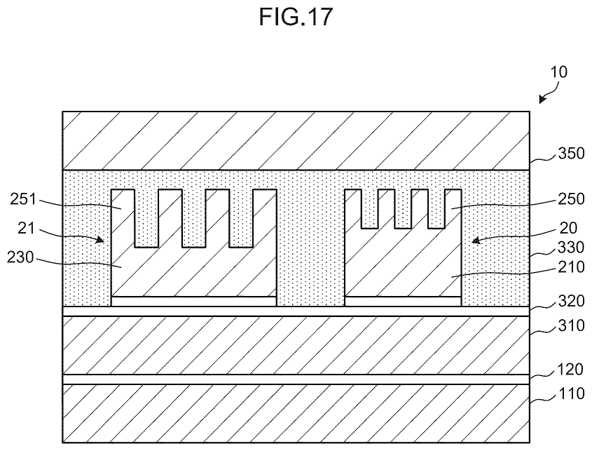

FIG. 17 is a view illustrating another configuration example of the semiconductor device according to the fourth embodiment of the present disclosure. FIG. 17 is a schematic cross-sectional view illustrating a configuration example of the semiconductor device 10 similarly to FIG. 16. The semiconductor device 10 in FIG. 17 is different from the semiconductor device 10 in FIG. 16 in that a second semiconductor substrate 210 of the semiconductor chip 20 and a second semiconductor substrate 230 of the semiconductor chip 21 are different in thickness.

As illustrated in FIG. 17, the heights of a protrusion 250 of the semiconductor chip 20 and a protrusion 251 of the semiconductor chip 21 can be adjusted to align the height from a bonding surface to an end portion of the protrusion. As a result, an increase in a step of a covering member 330 can be prevented.

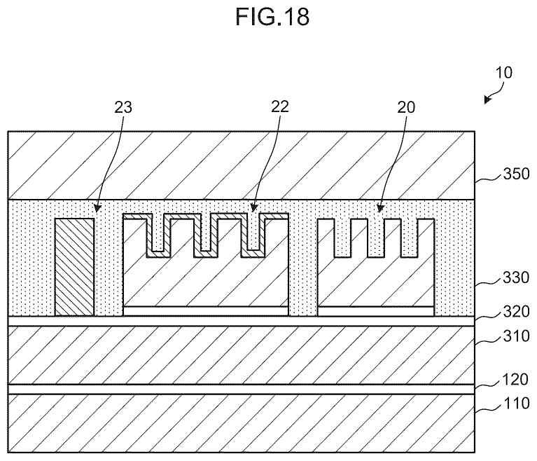

FIG. 18 is a view illustrating another configuration example of the semiconductor device according to the fourth embodiment of the present disclosure. FIG. 18 is a schematic cross-sectional view illustrating a configuration example of the semiconductor device 10 similarly to FIG. 16. The semiconductor device 10 in FIG. 18 is different from the semiconductor device 10 in FIG. 16 in including a semiconductor chip 22 described in FIG. 13 instead of a semiconductor chip 21 and further including a chip 23.

The chip 23 is a chip includes a member having a thermal conductivity higher than that of the second semiconductor substrate 210. The chip 23 constitutes a heat dissipation path of the imaging element 100 and the memory chip 300. The heat dissipation capability of the semiconductor device 10 can be improved by the chip 23 and the semiconductor chip 22.

In addition, by arranging the chip 23 in the empty region, the step of the covering member 330 can be further reduced.

Since the configuration of the semiconductor device 10 other than the above is similar to the configuration of the semiconductor device 10 in the first embodiment of the present disclosure, the description thereof will be omitted.

Although each of the embodiments of the present disclosure has been described above, the technical scope of the present disclosure is not limited to each of the above-described embodiments as it is, and various modifications can be made without departing from the gist of the present disclosure. In addition, components of different embodiments and modifications may be appropriately combined.

Note that the effects described in the present specification are merely examples and are not limited, and other effects may be provided.

Note that the present technology can also have the following configurations.

(1) A semiconductor device comprising:
a first semiconductor substrate;
a second semiconductor substrate that is bonded to the first semiconductor substrate and includes a protrusion on a surface different from a surface to be bonded; and
a covering member that covers the second semiconductor substrate bonded to the first semiconductor substrate.
   (2) The semiconductor device according to the above (1), wherein the protrusion includes a same member as the second semiconductor substrate.
   (3) The semiconductor device according to the above (1), wherein the protrusion includes a member having a thermal conductivity higher than that of the second semiconductor substrate.
   (4) The semiconductor device according to the above (1), wherein the protrusion includes a member that suppresses etching of the second semiconductor substrate.
   (5) The semiconductor device according to the above (1), wherein the protrusion includes any of silicon carbide, aluminum nitride, and silicon nitride.
   (6) The semiconductor device according to any one of the above (1) to (5), wherein the protrusion has a shape in which a height is smaller than a thickness of the second semiconductor substrate.
   (7) The semiconductor device according to any one of the above (1) to (6), wherein the protrusion is formed in a wall shape along an end portion of the second semiconductor substrate.
   (8) The semiconductor device according to any one of the above (1) to (5), wherein the second semiconductor substrate includes a plurality of the protrusions.
   (9) The semiconductor device according to the above (8), wherein the protrusions are formed such that a ratio of a height of one of the protrusions to a distance to another adjacent one of the protrusions is 0.01 or less.
   (10) The semiconductor device according to the above (8), wherein the protrusions each have a shape in which a width is 0.5 mm or less.
   (11) The semiconductor device according to any one of the above (1) to (10), further comprising a plurality of the second semiconductor substrates.
   (12) The semiconductor device according to the above (11), wherein the plurality of second semiconductor substrates is formed such that a height from a bonding surface to a tip of the protrusion when the second semiconductor substrates are bonded to the first semiconductor substrate is substantially equal to each other.
   (13) The semiconductor device according to any one of the above (1) to (12), further comprising a third semiconductor substrate bonded to a surface of the second semiconductor substrate on a side on which the protrusion is arranged.

### REFERENCE SIGNS LIST

10 SEMICONDUCTOR DEVICE
20 to 22 SEMICONDUCTOR CHIP
23 CHIP
100 IMAGING ELEMENT
110 FIRST SEMICONDUCTOR SUBSTRATE
210, 230 SECOND SEMICONDUCTOR SUBSTRATE
250, 251 PROTRUSION
255 COATING FILM
300 MEMORY CHIP
310 FOURTH SEMICONDUCTOR SUBSTRATE
330 COVERING MEMBER
350 THIRD SEMICONDUCTOR SUBSTRATE

1. A semiconductor device comprising:
a first semiconductor substrate;
a second semiconductor substrate that is bonded to the first semiconductor substrate and includes a protrusion on a surface different from a surface to be bonded; and
a covering member that covers the second semiconductor substrate bonded to the first semiconductor substrate.

2. The semiconductor device according to claim 1, wherein the protrusion includes a same member as the second semiconductor substrate.

3. The semiconductor device according to claim 1, wherein the protrusion includes a member having a thermal conductivity higher than that of the second semiconductor substrate.

4. The semiconductor device according to claim 1, wherein the protrusion includes a member that suppresses etching of the second semiconductor substrate.

5. The semiconductor device according to claim 1, wherein the protrusion includes any of silicon carbide, aluminum nitride, and silicon nitride.

6. The semiconductor device according to claim 1, wherein the protrusion has a shape in which a height is smaller than a thickness of the second semiconductor substrate.

7. The semiconductor device according to claim 1, wherein the protrusion is formed in a wall shape along an end portion of the second semiconductor substrate.

8. The semiconductor device according to claim 1, wherein the second semiconductor substrate includes a plurality of the protrusions.

9. The semiconductor device according to claim 8, wherein the protrusions are formed such that a ratio of a height of one of the protrusions to a distance to another adjacent one of the protrusions is 0.01 or less.

10. The semiconductor device according to claim 8, wherein the protrusions each have a shape in which a width is 0.5 mm or less.

11. The semiconductor device according to claim 1, further comprising a plurality of the second semiconductor substrates.

12. The semiconductor device according to claim 11, wherein the plurality of second semiconductor substrates is formed such that a height from a bonding surface to a tip of the protrusion when the second semiconductor substrates are bonded to the first semiconductor substrate is substantially equal to each other.

13. The semiconductor device according to claim 1, further comprising a third semiconductor substrate bonded to a surface of the second semiconductor substrate on a side on which the protrusion is arranged.
